(19) United States
(12) Patent Application Publication
(10) Pub. No.: US 2008/0096331 A1
(43) Pub. Date: Apr. 24, 2008

(54) METHOD FOR FABRICATING HIGH COMPRESSIVE STRESS FILM AND STRAINED-SILICON TRANSISTORS

(76) Inventors: Neng-Kuo Chen, Hsin-Chu City (TW); Teng-Chun Tsai, Hsin-Chu City (TW); Chien-Chung Huang, Tai-Chung Hsien (TW)

Correspondence Address: NORTH AMERICA INTELLECTUAL PROPERTY CORPORATION, P.O. BOX 506, MERRIFIELD, VA, 22116, US

(21) Appl. No.: 11/538,803

(22) Filed: Oct. 4, 2006

(51) Int. Cl. H01L 21/84; H01L 21/8234; H01L 21/469; H01L 21/31; H01L 21/336

(52) U.S. Cl. 438/151; 438/778; 438/197; 438/299

(57) ABSTRACT

A method for fabricating strained silicon transistors is disclosed. First, a semiconductor substrate is provided, in which the semiconductor substrate includes a gate, at least a spacer, and a source/drain region formed thereon. Next, a precursor, silane, and ammonia are injected, in which the precursor is reacted with silane and ammonia to form a high compressive stress film on the surface of the gate, the spacer, and the source/drain region. Preferably, the high compressive stress film can be utilized in the fabrication of a poly stressor, a contact etch stop layer, and dual contact etch stop layers.

### BACKGROUND OF THE INVENTION

1. Field of the Invention

The invention relates to a method for fabricating a high stress film, and more particularly, to a method for forming a high compressive stress film on a strained-silicon transistor.

2. Description of the Prior Art

As semiconductor technology advances and development of integrated circuits continues to revolution, the computing power and storage capacity enjoyed by computers also increases exponentially. As a result, this growth further fuels the expansion of related industries. As predicted by Moores Law, the number of transistors utilized in integrated circuits has doubled every 18 months and semiconductor processes also have advanced from 0.18 micron in 1999, 0.13 micron in 2001, 90 nanometer (0.09 micron) in 2003, to 65 nanometer (0.065 micron) in 2005.

As the semiconductor processes advance, determining methods for increasing the driving current for metal oxide semiconductor (MOS) transistors for fabrication processes under 65 nanometers has become an important topic. Currently, the utilization of high stress films to increase the driving current of MOS transistors is divided into two categories. The first category is that being a poly stressor formed before the formation of nickel suicides. The second category being a contact etch stop layer (CESL) formed after the formation of the nickel silicides.

In general, the thermal budget for the fabrication of poly stressors can be greater than 100° C. However, due to the intolerability to overly high temperatures of the nickel silicides, the thermal budget for the fabrication of contact etch stop layer should be maintained below 430° C. In the past, the fabrication of the high stress films involved the deposition of a film composed of silicon nitride (SiN), in which the film was utilized to increase the driving current of the MOS transistor.

Please refer to FIG. 1 through FIG. 3. FIG. 1 through FIG. 3 are perspective diagrams showing the means of fabricating a strained-silicon PMOS transistor according to the prior art. As shown in FIG. 1, a semiconductor substrate 10 is provided and a gate structure 12 is formed on the semiconductor substrate 10, in which the gate structure 12 includes a gate oxide layer 14, a gate 16 disposed on the gate oxide layer 14, a cap layer 16 disposed on the gate 16, and an oxide-nitride-oxide (ONO) offset spacer 20. Preferably, the gate oxide layer 14 is composed of silicon dioxide, the gate 16 is composed of doped polysilicon, and the cap layer 18 is composed of silicon nitride to protect the gate 16. Additionally, a shallow trench isolation (STI) 22 is formed around the active area of the gate structure 21 within the semiconductor substrate 10.

As shown in FIG. 2, an ion implantation process is performed to form a source/drain region 26 in the semiconductor substrate 10 around the spacer 20. Next, a metal, such as a nickel layer (not shown), is sputtered on the surface of the semiconductor substrate 10 and the gate structure 12, and a rapid thermal annealing (RTA) process is performed to react the metal with the gate 16 and part of the source/drain region 26 and form a silicide layer. The un-reacted metal is removed thereafter.

As shown in FIG. 3, a plasma enhanced chemical vapor deposition (PECVD) process is performed by injecting silane (SiH₄) and ammonia (NH₃) to form a high compressive stress film 28 on the surface of the gate structure 12 and the source/drain region 26. The high compressive stress film 28 is then utilized to compress the region below the gate 16, such as the channel region of the semiconductor substrate 10, thereby increasing the hole mobility in the channel region and the driving current of the strained-silicon PMOS transistor.

In general, the conventional method often utilizes a means of adjusting the high frequency and low frequency power of the fabrication equipment or increasing the ratio of silane and ammonia to fabricate a high compressive stress film with higher quality. However, the conventional method utilizing a PECVD process under 400° C. is able to fabricate an as-deposite film with a maximum stress of only −1.6 GPa. Consequently, the insufficient stress of the film will not only affect the compressive ability of the film in the later process, but also significantly influence the driving current of the MOS transistor. Hence, finding methods for effectively increasing the stress of the high compressive stress film has become a critical task in the industry.

### SUMMARY OF THE INVENTION

It is therefore an objective of the present invention to provide a method for fabricating a strained-silicon transistor to effectively improve the stress of the high compressive stress film.

According to the present invention, a method for fabricating a strained-silicon transistor includes the following steps. First, a semiconductor substrate is provided, and a gate, at least a spacer, and a source/drain region are formed on the semiconductor substrate. Next, a precursor, silane, and ammonia are injected, such that the precursor is reacted with silane and ammonia to form a high compressive stress film on the surface of the gate and the source/drain region.

Preferably, the present invention first injects a precursor composed of tetra-methyl-silane, ether, aldehyde, or carboxylic acid, and then reacts the precursor with silane and ammonia to form various impurity bonds such as Si—R and/or Si—O—R, in which the impurity bonds function to increase the stress of the high compressive stress film. Additionally, the method for fabricating the high compressive stress film can be applied to the fabrication of poly stressor, the fabrication of contact etch stop layer, and the fabrication of dual contact etch stop layer for improving the efficiency and performance of the strained-silicon transistor.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 through FIG. 3 are perspective diagrams showing the means of fabricating a strained-silicon PMOS transistor according to the prior art.

FIG. 4 through FIG. 6 are perspective diagrams showing a means of fabricating a high compressive stress film on a PMOS transistor according to the present invention.

FIG. 7 is a perspective diagram showing the Fourier Transform Infrared Spectroscopy of the high compressive stress film of the present invention.

FIG. 8 is a comparative diagram showing the PMOS ion gain and stress comparison between the conventional high compressive stress film and the high compressive stress film of the present invention.

FIG. 9 is a perspective diagram showing a relationship between the high compressive stress film and the PMOS ion gain according to the present invention.

FIG. 10 through FIG. 12 are perspective diagrams showing a means of fabricating a contact etch stop layer (CESL) according to another embodiment of the present invention.

FIG. 13 through FIG. 18 are perspective diagrams showing a means of fabricating a dual contact etch stop layer (dual CESL) according to another embodiment of the present invention.

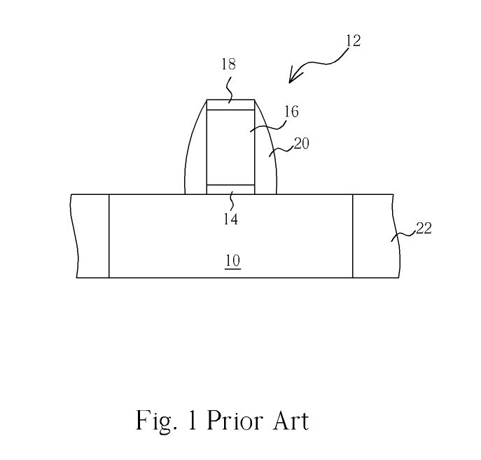

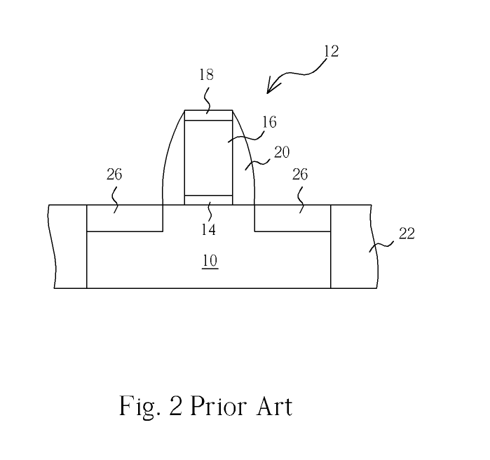

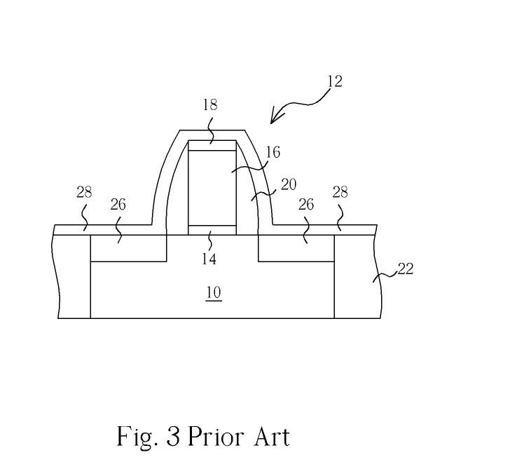

### DETAILED DESCRIPTION

Certain terms are used throughout the following description and claims to refer to particular system components. As one skilled in the art will appreciate, consumer electronic equipment manufacturers may refer to a component by different names. This document does not intend to distinguish between components that differ in name but not function. In the following discussion and in the claims, the terms “including” and “comprising” are used in an open-ended fashion, and thus should be interpreted to mean “including, but not limited to . . .”. The terms “couple” and “couples” are intended to mean either an indirect or a direct electrical connection. Thus, if a first device couples to a second device, that connection may be through a direct electrical connection, or through an indirect electrical connection via other devices and connections.

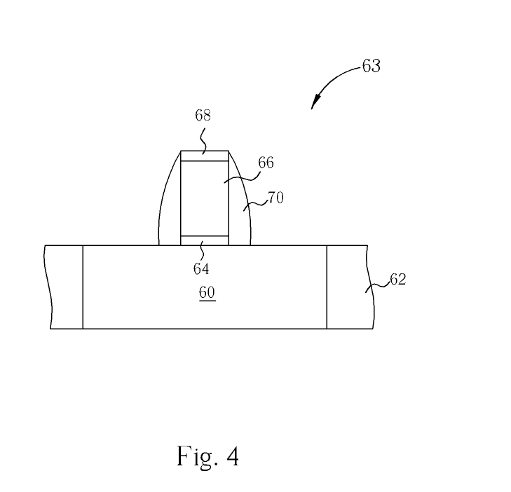

Please refer to FIG. 4 through FIG. 6. FIG. 4 through FIG. 6 are perspective diagrams showing a means of fabricating a high compressive stress film on a PMOS transistor according to the present invention. As shown in FIG. 4, a semiconductor substrate 60, such as a wafer or a silicon on insulator (SOI) substrate is provided, in which the semiconductor substrate 60 includes a gate structure 63 thereon. The gate structure 63 includes a gate dielectric 64, a gate 66 disposed on the gate dielectric 64, a cap layer 68 disposed on top of the gate 66, and an ONO offset spacer 70. Preferably, the gate dielectric 64 is composed of insulating materials, such as silicon dioxide, the gate 66 is composed of doped polysilicon, and the cap layer 68 is composed of silicon nitride to protect the gate 66. Additionally, a shallow trench isolation (STI) 62 is formed around the active area of the gate structure 63 within the semiconductor substrate 60.

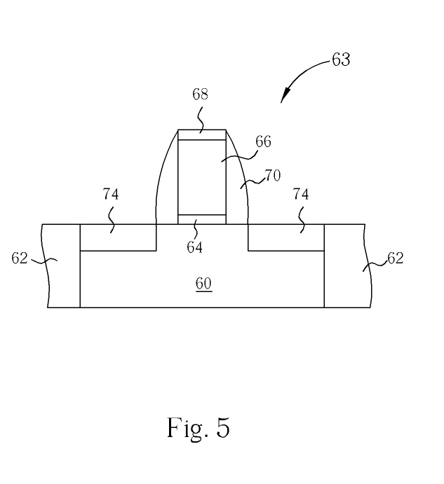

As shown in FIG. 5, an ion implantation process is performed to form a source/drain region 74 around the gate structure 63 and within the semiconductor substrate 60. Next, a rapid thermal annealing process is performed to utilize a temperature between 900° C. to 1050° C. to active the dopants within the source/drain region 74 and repair the lattice structure of the semiconductor substrate 60, which has been damaged during the ion implantation process. Additionally, a lightly doped drain (LDD) or a source/drain extension can be formed between the source/drain region 74 and the gate structure 63, and a salicide layer can be formed on the surface of the source/drain region 74 and the gate structure 63. It is to be understood that the fabrication of the lightly doped rain, the source/drain extension, and the salicide layer relating to the present invention method is well known by those of average skill in the art and thus not further explained herein.

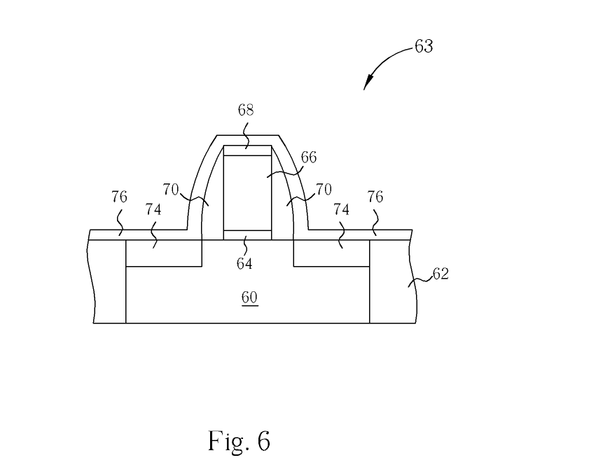

As shown in FIG. 6, a plasma enhanced chemical vapor deposition (PECVD) process is performed to form a high compressive stress film 76 on the gate structure 63 and the source/drain region 74. According to a preferred embodiment of the present invention, the PECVD process involves first placing the semiconductor chamber 60 in a reaction chamber, and injecting a precursor composed of tetra-methyl-silane, ether, aldehyde, or carboxylic acid into the chamber thereafter. Next, silane and ammonia are injected into the reaction chamber to form a high compressive stress film 76 on the surface of the gate structure 63 and the source/drain region 74. Preferably, the amount of the precursor being utilized is between 30 grams to 3000 grams, the flow rate of silane is between 30 sccm to 3000 sccm, and the flow rate of ammonia is between 30 sccm to 2000 sccm. Additionally, the power of a high frequency and low frequency source utilized to form the high compressive stress film 76 is between 50 watts to 3000 watts.

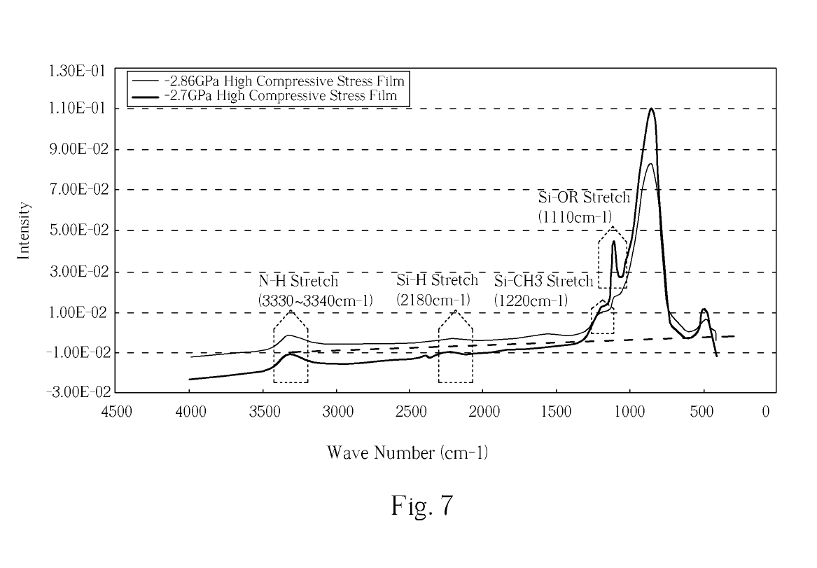

It should be noted that while the PECVD process is performed, the injected precursor will react with silane and ammonia to generate numerous impurity bonds, such as O/CH₃/O—CH₃. Please refer to FIG. 7. FIG. 7 is a perspective diagram showing the Fourier Transform Infrared Spectroscopy of the high compressive stress film of the present invention. As shown in FIG. 7, by reacting the precursor with silane and ammonia, the high compressive stress film 76 produced from the PECVD process is able to generate Si—O—R and/or Si—R impurity bonds such as Si—O—(CH₃) and Si—CH₃ under a pressure of −2.86 GPa and −2.7 GPa, in which the impurity bonds function to increase the stress of the high compressive stress film 76. Consequently, the high compressive stress film 76 is utilized to compress the region below the gate 66, such as the lattice arrangement within the channel region of the semiconductor substrate 60, thereby increasing the hole mobility and the driving current of the PMOS transistor.

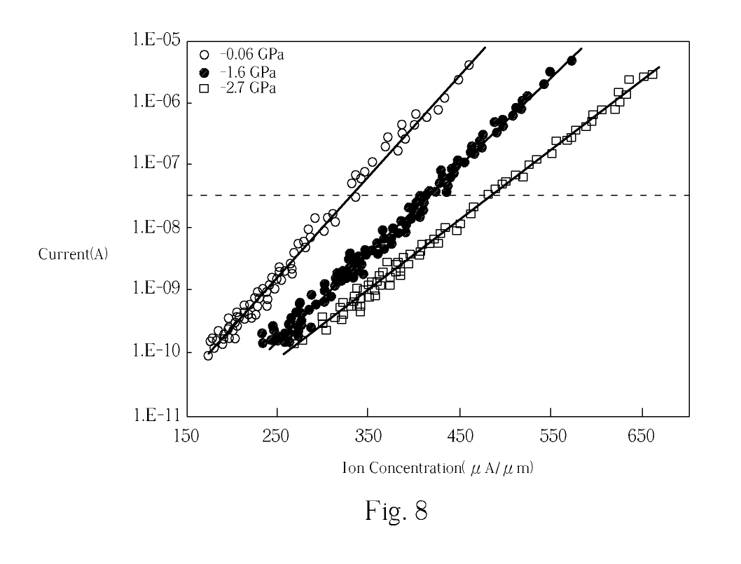

Please refer to FIG. 8. FIG. 8 is a comparative diagram showing the PMOS ion gain and stress comparison between the conventional high compressive stress film and the high compressive stress film of the present invention. As shown in FIG. 8, when the deposition depth of the conventional high compressive stress film and the high compressive stress film of the present invention are both 1000 angstroms, the present invention is able to significantly increase the stress of an as-deposite film from −1.6 GPa to −2.7 GPa, and increase the PMOS ion gain from 24% to 45%.

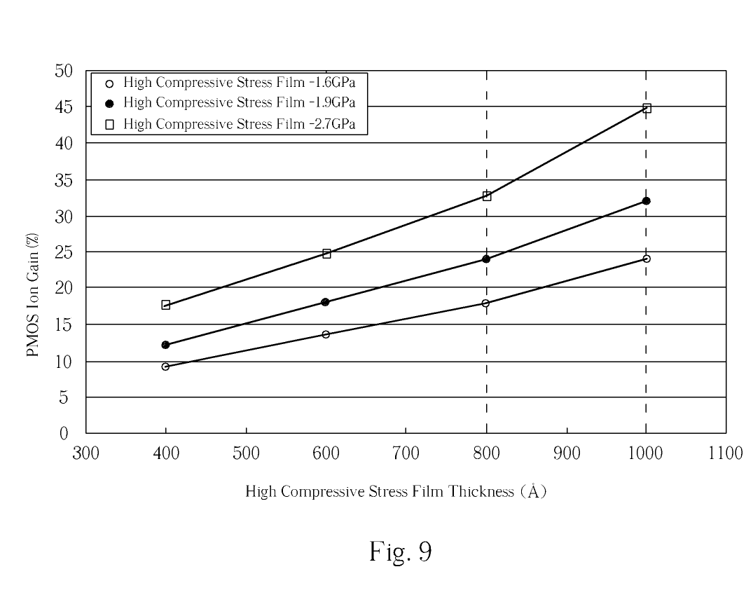

Please refer to FIG. 9. FIG. 9 is a perspective diagram showing a relationship between the high compressive stress film and the PMOS ion gain according to the present invention. As shown in FIG. 9, by setting PMOS ion gain at 20% and maintaining the stress of the high compressive stress film at −1.6 GPa, the thickness of the high compressive stress film fabricated is approximately 850 angstroms. Preferably, the present invention is able to significantly increase the stress of the film up to −2.7 GPa. Hence, a high compressive stress film having a thickness of approximately 450 angstroms can be fabricated under the same condition of setting the PMOS ion gain at 20%. By reducing the thickness of the high compressive stress film, the process window for etching the contact plugs performed in a later process can be increased significantly. Additionally, if the stress of the film is maintained at −2.7 GPa while keeping other factors constant, the thickness of the film can be increased to 1000 angstroms and the PMOS ion gain can be increased to 45%.

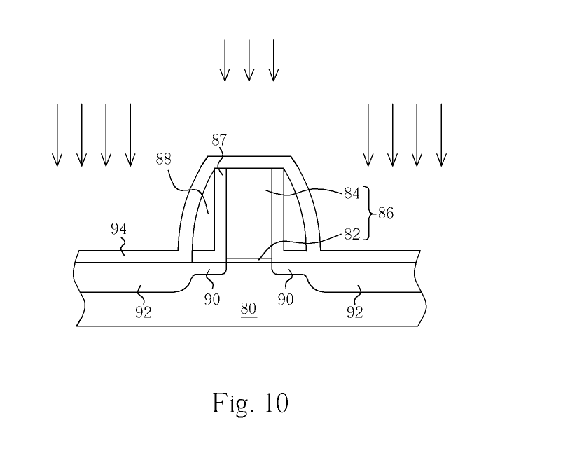

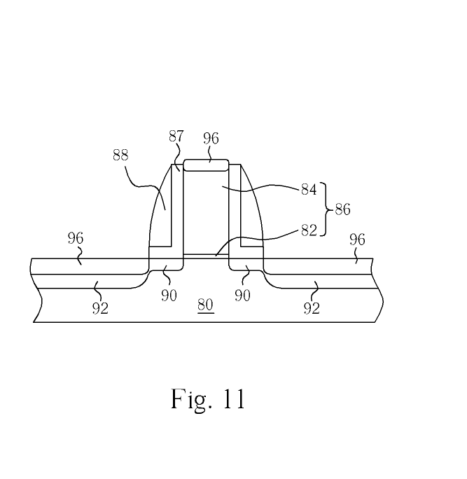

Please refer to FIG. 10 through FIG. 12. FIG. 10 through FIG. 12 are perspective diagrams showing a means of fabricating a contact etch stop layer (CESL) according to another embodiment of the present invention. As shown in FIG. 10, a semiconductor substrate 80 is first provided, and a gate structure 86 having a gate 84 and a gate dielectric 82 is formed on the semiconductor substrate 80. Next, an ion implantation process is performed to form a lightly doped rain 90 within the semiconductor substrate 80. A liner 87 and a spacer 88 are formed on the sidewall of the gate structure 86 thereafter, and another ion implantation process is performed to form a source/drain region 92 around the spacer 88 and within the semiconductor substrate 80. Next, a metal layer 94, such as a nickel layer is sputtered on the surface of the semiconductor substrate 80 and covering the gate 84, the spacer 88, and the source/drain region 92. As shown in FIG. 11, a rapid thermal annealing process is performed to react the metal layer 94 with the gate 84 and the source/drain region 92 to form a plurality of silicide layers 96. The un-reacted metal layer 94 is removed thereafter.

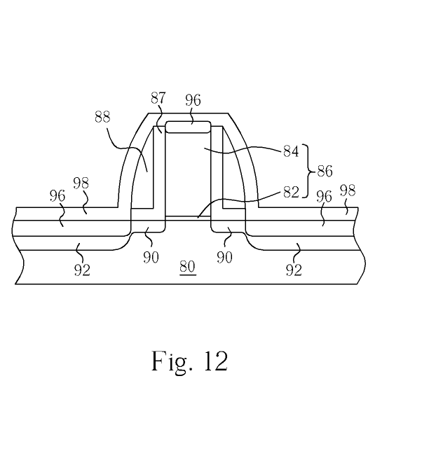

As shown in FIG. 12, a PECVD process is performed to form a high compressive stress film 94 on the gate structure 86, the spacer 88, and the source/drain region 92. According to a preferred embodiment of the present invention, the PECVD process involves first placing the semiconductor chamber 80 in a reaction chamber, and injecting a precursor composed of tetra-methyl-silane, ether, aldehyde, or carboxylic acid into the reaction chamber thereafter. Next, silane and ammonia are injected into the reaction chamber, such that the precursor will react with silane and ammonia to form a plurality of impurity bonds, such as O/CH₃/O—CH₃. After reacting the precursor with silane and ammonia, a contact etch stop layer 98 containing bonds including Si—CH₃ and Si—O—R is formed on the surface of the gate structure 86, the spacer 88, and the source/drain region 92. Preferably, the amount of the precursor being utilized is between 30 grams to 3000 grams, the flow rate of silane is between 30 sccm to 3000 sccm, and the flow rate of ammonia is between 30 sccm to 2000 sccm. Additionally, the power of a high frequency and low frequency source utilized to form the contact etch stop layer 98 is between 50 watts to 3000 watts.

After the formation of the contact etch stop layer 98, an inter-layer dielectric (ILD) (not shown) is disposed thereon. Next, an anisotropic etching process is performed by utilizing a patterned photoresist (not shown) as an etching mask to form a plurality of contact plugs (not shown) within the inter-layer dielectric. The contact plugs are utilized as bridges for contacting other electronic devices.

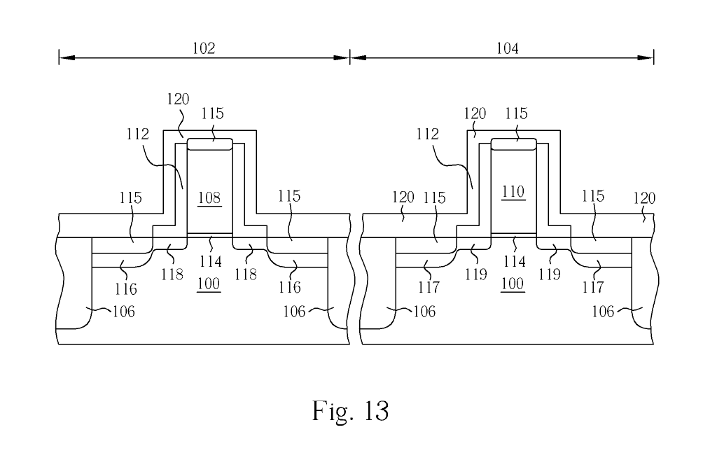

Please refer to FIG. 13 through FIG. 18. FIG. 13 through FIG. 18 are perspective diagrams showing a means of fabricating a dual contact etch stop layer (dual CESL) according to another embodiment of the present invention. As shown in FIG. 12, a semiconductor substrate 100 having an NMOS region 102 and a PMOS region 104 is provided, in which the NMOS region 102 and the PMOS region 104 is divided by a shallow trench isolation 106. The NMOS region 102 and the PMOS region 104 each includes an NMOS gate 108, a PMOS gate 110, and a gate dielectric 114 disposed between the NMOS gate 108, the PMOS gate 110, and the semiconductor substrate 100 respectively. A liner 112 composed of silicon oxide and silicon nitride is formed on the sidewall of the NMOS gate 108 and the PMOS gate 110 thereafter.

Next, an ion implantation process is performed to form a source/drain region 116 around the NMOS gate 108 and a source/drain region 117 around the PMOS gate 110 and within the semiconductor substrate 100. A rapid thermal annealing process is performed thereafter to utilize a temperature between 900° C. to 1050° C. to active the dopants within the source/drain region 116 and 117 and repair the lattice structure of the semiconductor substrate 60, which has been damaged during the ion implantation process. Additionally, a lightly doped drain (LDD) 118 and 119 can be formed between the source/drain region 116, 117 and the gate structure 108, 110.

Next, a metal layer (not shown), such as a nickel layer is sputtered on the surface of the semiconductor substrate 100, and a rapid thermal annealing process is performed to react the metal layer with the NMOS gate 108, the PMOS gate 110, and the source/drain region 116 and 117 to form a plurality of silicide layers 115.

After the un-reacted metal layer is removed, a PECVD process is performed to form a high tensile stress film 120 over the surface of the silicide layers 115 within the NMOS region 102 and the PMOS region 104.

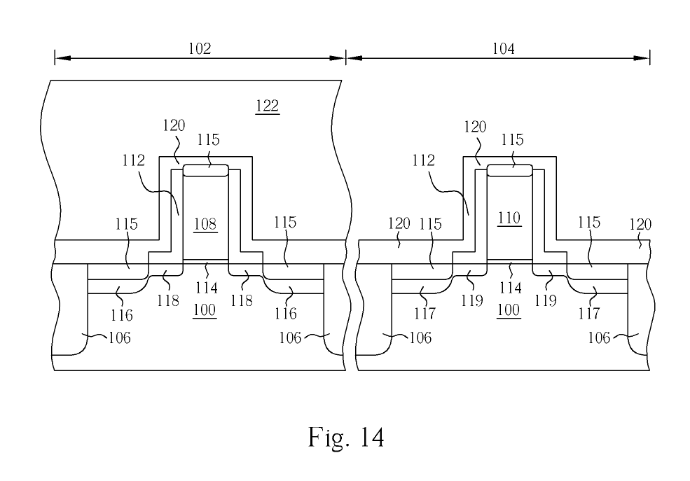

As shown in FIG. 14, a series of coating, exposure, and development processes are performed to form a patterned photoresist 122 on the NMOS region 102. Next, an etching process is performed to remove the high tensile stress film 120 disposed on the PMOS region 104, thereby leaving a high tensile stress film 120 on the NMOS gate 108 and the source/drain region 116 of the NMOS region 120.

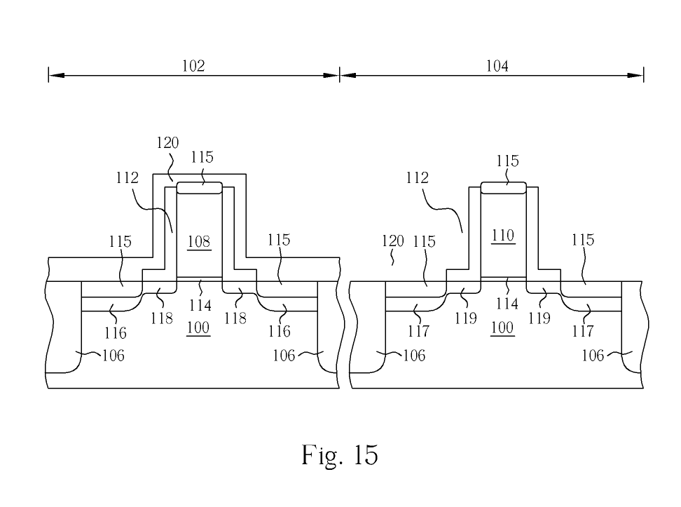

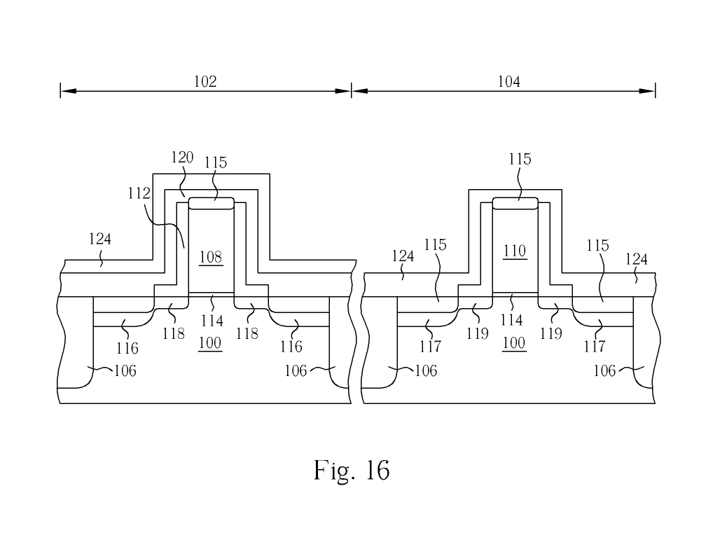

As shown in FIG. 15, the patterned photoresist 122 disposed on the NMOS region 102 is removed thereafter. As shown in FIG. 16, a PECVD process is performed, in which the PECVD process involves first placing the semiconductor chamber 100 in a reaction chamber, and injecting a precursor composed of tetra-methyl-silane, ether, aldehyde, or carboxylic acid into the chamber thereafter. Next, silane and ammonia are introduced into the reaction chamber, such that the precursor is reacted with silane and ammonia to form a high compressive stress film 124 on the NMOS region 102 and the PMOS region 104. Preferably, the amount of the precursor being utilized is between 30 grams to 3000 grams, the flow rate of silane is between 30 sccm to 3000 sccm, and the flow rate of ammonia is between 30 sccm to 2000 sccm. Additionally, the power of a high frequency and low frequency source utilized to form the high compressive stress film 124 is between 50 watts to 3000 watts.

As described in the aforementioned embodiments, the reaction between the precursor and the injected silane and ammonia will generate various impurity bonds including Si—CH₃ and Si—O—R, such that these bonds can be further utilized to enhance the compression ability of the high compressive stress film 124.

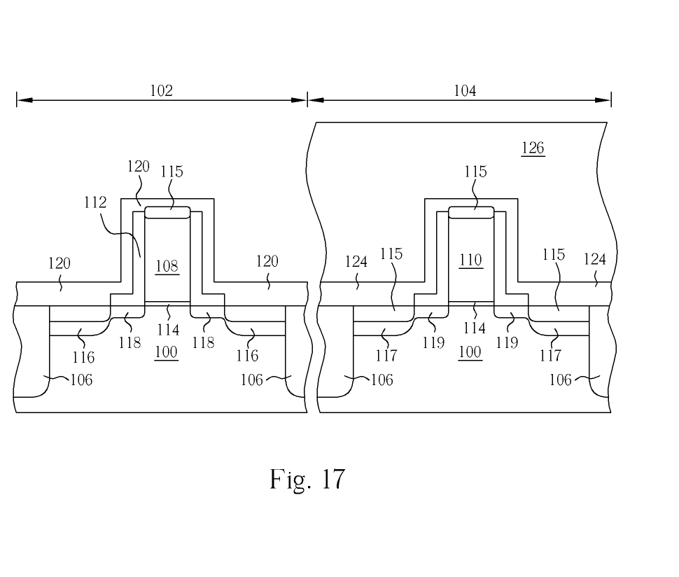

As shown in FIG. 17, a series of coating, exposure, and development processes are performed to form a patterned photoresist 126 on the PMOS region 104. Next, an etching process is performed to remove the high compressive stress film 124 disposed on the NMOS region 102, thereby leaving a high compressive stress film 124 on the surface of the PMOS gate 110 and the source/drain region 117. The patterned photoresist 126 disposed on the PMOS region 104 is removed thereafter.

According to the embodiment for fabricating the dual CESL, the high tensile stress film 120 can be utilized to stretch the lattice structure below the NMOS gate 108, whereas the high compressive stress film 124 can be utilized to compress the lattice structure below the PMOS gate 110, thereby increasing the driving current for both NMOS and PMOS transistors.

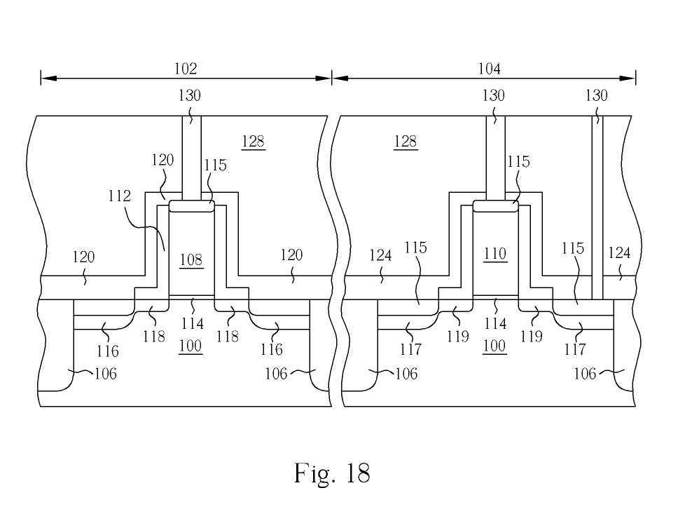

As shown in FIG. 18, an inter-layer dielectric 128 is disposed on the high tensile stress film 120 and the high compressive stress film 124. Next, an anisotropic etching process is performed by utilizing a patterned photoresist (not shown) as an etching mask and utilizing the high tensile stress film 120 and the high compressive stress film 124 as a contact etch stop layer to form a plurality of contact plugs 130 within the inter-layer dielectric 128. The contact plugs 130 are utilized as a bridge for connecting other electronic devices in the later process.

Alternatively, the present invention is able to first form a high compressive stress film on the PMOS transistor, perform a series of required etching process, and then form a high tensile stress film on the NMOS transistor. Subsequently, an inter-layer dielectric layer and a plurality of contact plugs formed in the inter-layer dielectric are formed on the high tensile stress film and the high compressive stress film.

In contrast to the conventional method of forming high compressive stress film, the present invention first injects a precursor composed of tetra-methyl-silane, ether, aldehyde, or carboxylic acid, and reacts the precursor with silane and ammonia to form various impurity bonds such as Si—R and Si—O—R, in which the impurity bonds function to significantly increase the stress of the high compressive stress film. Additionally, the method for fabricating the high compressive stress film can be applied to the fabrication of poly stressor, the fabrication of contact etch stop layer, and the fabrication of dual contact etch stop layer for improving the efficiency and performance of the strained-silicon transistor.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A method for fabricating a strained-silicon transistor, comprising:
providing a semiconductor substrate;
forming a gate, at least a spacer, and a source/drain region on the semiconductor substrate;
injecting a precursor;
injecting silane and ammonia; and
reacting the precursor with silane and ammonia to form a high compressive stress film on the surface of the gate and the source/drain region.

2. The method for fabricating strained-silicon transistors of claim 1, wherein the semiconductor substrate comprises a wafer or a silicon on insulator (SOI) substrate.

3. The method for fabricating strained-silicon transistors of claim 1 further comprising forming a gate dielectric between the gate and the semiconductor substrate.

4. The method for fabricating strained-silicon transistors of claim 1, wherein the precursor comprises tetra-methyl-silane, ether, aldehyde, or carboxylic acid.

5. The method for fabricating strained-silicon transistors of claim 1, wherein the amount of the precursor being utilized is between 30 gram to 3000 gram.

6. The method for fabricating strained-silicon transistors of claim 1, wherein the flow rate of silane is between 30 sccm to 3000 sccm.

7. The method for fabricating strained-silicon transistors of claim 1, wherein the flow rate of ammonia is between 30 sccm to 2000 sccm.

8. The method for fabricating strained-silicon transistors of claim 1 further comprising performing a rapid thermal annealing process after the formation of the high compressive stress film.

9. The method for fabricating strained-silicon transistors of claim 1, wherein the strained-silicon transistor is a strained-silicon PMOS transistor.

10. The method for fabricating strained-silicon transistors of claim 1, wherein the step of forming the high compressive stress film comprises performing a plasma enhanced chemical vapor deposition (PECVD) process.

11. The method for fabricating strained-silicon transistors of claim 1, wherein the power of a high frequency and a low frequency source utilized for forming the high compressive stress film is between 50 watts and 3000 watts.

12. A method for fabricating a high compressive stress film, comprising:
reacting a precursor with silane and ammonia to form a high compressive stress film, wherein the high compressive stress film comprises Si—R bonds.

13. The method for fabricating the high compressive stress film of claim 12, wherein the precursor comprises tetra-methyl-silane, ether, aldehyde, or carboxylic acid.

14. The method for fabricating the high compressive stress film of claim 12, wherein the amount of the precursor being utilized is between 30 gram to 3000 gram.

15. The method for fabricating the high compressive stress film of claim 12, wherein the flow rate of silane is between 30 sccm to 3000 sccm.

16. The method for fabricating the high compressive stress film of claim 12, wherein the flow rate of ammonia is between 30 sccm to 2000 sccm.

17. The method for fabricating the high compressive stress film of claim 12, wherein the power of a high frequency and a low frequency source utilized for forming the high compressive stress film is between 50 watts and 3000 watts.

18. The method for fabricating the high compressive stress film of claim 12, wherein the Si—R bonds comprise Si—CH₃ bond.

19. A method for fabricating a high compressive stress film, comprising:
reacting a precursor with silane and ammonia to form a high compressive stress film, wherein the high compressive stress film comprises Si—O—R bonds.

20. The method for fabricating the high compressive stress film of claim 19, wherein the precursor comprises tetra-methyl-silane, ether, aldehyde, or carboxylic acid.

21. The method for fabricating the high compressive stress film of claim 19, wherein the amount of the precursor being utilized is between 30 gram to 3000 gram.

22. The method for fabricating the high compressive stress film of claim 19, wherein the flow rate of silane is between 30 sccm to 3000 sccm.

23. The method for fabricating the high compressive stress film of claim 19, wherein the flow rate of ammonia is between 30 sccm to 2000 sccm.

24. The method for fabricating the high compressive stress film of claim 19, wherein the power of a high frequency and a low frequency source utilized for forming the high compressive stress film is between 50 watts and 3000 watts.

25. The method for fabricating the high compressive stress film of claim 19, wherein the Si—O—R bonds comprise Si—O—(CH₃) bond.

26. A strained-silicon transistor, comprising:
a semiconductor substrate;
a gate disposed on the semiconductor substrate;
at least a spacer disposed on the sidewall of the gate;
a source/drain region formed in the semiconductor substrate;
a plurality of silicide layers disposed on top of the gate and the surface of the source/drain region; and
a high compressive stress film disposed on the gate, the spacer, and the source/drain region, wherein the high compressive stress film comprises Si—R bonds.

27. The strained-silicon transistor of claim 26 further comprising a gate dielectric disposed below the gate.

28. The strained-silicon transistor of claim 26 further comprising a liner disposed between the sidewall of the gate and the spacer.

29. The strained-silicon transistor of claim 26 further comprising a source/drain extension region disposed below the spacer and within the semiconductor substrate.

30. The strained-silicon transistor of claim 26, wherein the silicide layers comprise nickel silicide.

31. The strained-silicon transistor of claim 26, wherein the strained-silicon transistor is a strained-silicon PMOS transistor.

32. The strained-silicon transistor of claim 26, wherein the Si—R bonds comprise Si—CH₃ bond.

33. A strained-silicon transistor, comprising:
a semiconductor substrate;
a gate disposed on the semiconductor substrate;
at least a spacer disposed on the sidewall of the gate;
a source/drain region formed in the semiconductor substrate;
a plurality of silicide layers disposed on top of the gate and the surface of the source/drain region; and
a high compressive stress film disposed on the gate, the spacer, and the source/drain region, wherein the high compressive stress film comprises Si—O—R bonds.

34. The strained-silicon transistor of claim 33 further comprising a gate dielectric disposed below the gate.

35. The strained-silicon transistor of claim 33 further comprising a liner disposed between the sidewall of the gate and the spacer.

36. The strained-silicon transistor of claim 33 further comprising a source/drain extension region disposed below the spacer and within the semiconductor substrate.

37. The strained-silicon transistor of claim 33, wherein the silicide layers comprise nickel silicide.

38. The strained-silicon transistor of claim 33, wherein the strained-silicon transistor is a strained-silicon PMOS transistor.

39. The strained-silicon transistor of claim 33, wherein the Si—O—R bonds comprise Si—O—(CH₃) bond.
